(19) United States
(12) Patent Application Publication
(10) Pub. No.: US 2008/0054410 A1
(43) Pub. Date: Mar. 6, 2008

(54) Semiconductor Device and Fabricating Method Thereof

(76) Inventors: KYUNG MIN PARK, Namdong-gu (KR); Jae Won Han, Soowon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/846,082

(22) Filed: Aug. 28, 2007

(30) Foreign Application Priority Data
Aug. 29, 2006 (KR) 10-2006-0082441

(51) Int. Cl. H01L 29/06; H01L 21/4763

(52) U.S. Cl. 257/622; 438/618; 257/E29.005; 257/E21.495

(57) ABSTRACT

A semiconductor device for a system-in-a-package (SiP) is provided. The semiconductor device is defined with a plurality of circuit areas where a circuit is to be formed and a scribe lane partitioning a boundary between the circuit areas. A circuit unit is formed in the circuit areas, and a through-electrode is formed in the area defined as a scribe lane.

### CROSS-REFERENCE TO RELATED APPLICATION

The present application claims the benefit under 35 U.S.C. § 119 of Korean Patent Application No. 10-2006-0082441, filed Aug. 29, 2006, which is hereby incorporated by reference in its entirety.

### BACKGROUND

FIG. 1 is a concept view of a semiconductor device in a SiP (System In a Package) shape fabricated according to a related art fabricating method.

As shown in FIG. 1, the semiconductor device in a SiP shape according to the related art comprises an interposer 11, a first device 13, a second device 15, and a third device 17.

The first to third devices 13, 15, and 17 can, for example, be any one independently selected from a CPU (central processing unit), SRAM (static random access memory, DRAM (dynamic random access memory), Flash Memory, Logic LSI (large scale integrated), Power IC (integrated circuit), Control IC, Analog LSI, MM (monolithic microwave) IC, CMOS (complementary metal oxide semiconductor) RF-IC (radio frequency-IC), Sensor Chip, and MEMS (micro-electro-mechanical systems) Chip.

Connecting means for connecting signals between the respective devices are formed between the first device 13 and the second device 15, and between the second device 15 and the third device 17. It is important that the connecting means ensure unhindered communication of signals between the devices while being of simple form to ensure ease of fabrication.

A through-electrode can be proposed as one connecting means for connecting signals between the respective devices. The through-electrode, which is an electrode formed by penetrating the devices, can perform a function to electrically connect a device to the device stacked on the upper surface thereof. Also, the through-electrode can perform a function to electrically connect the corresponding device to the device stacked on the lower surface thereof.

Unfortunately, due to the three-dimensional aspect of the SiP shape, issues arise with respect to the placement of the through-electrode. For example, with highly integrated circuits and the need for an electrical connection between the devices stacked within the SiP shape, manufacturers have run into difficulty in fabricating semiconductor devices in a SiP shape that include through-electrode connecting means that are simple and easy to fabricate without damage of circuitry.

### BRIEF SUMMARY

Accordingly, embodiments of the present invention provide a semiconductor device and a fabricating method thereof, which can easily connect signals between a device positioned on the upper surface of a semiconductor device in a SiP (System In a Package) shape and a device positioned on the lower surface thereof.

A semiconductor device according to an embodiment, includes a plurality of circuit areas where a circuit is formed and a scribe lane partitioning a boundary between the circuit areas, a circuit unit formed in the circuit areas; and a through-electrode formed in the area defined as a scribe lane.

A fabricating method of a semiconductor device according to an embodiment comprises: preparing a semiconductor substrate defined with a plurality of circuit areas where a circuit is to be formed and a scribe lane partitioning the boundary between the circuit areas; forming a circuit unit in the circuit area of the semiconductor substrate; and forming a through-electrode in the area defined as the scribe lane.

### BRIEF DESCRIPTION OF THE DRAWINGS

FIG. 1 is a concept view of a semiconductor device in a SiP (System In a Package) fabricated according to a related art fabricating method.

FIGS. 2 and 3 are views for explaining a semiconductor device according to an embodiment of the present invention.

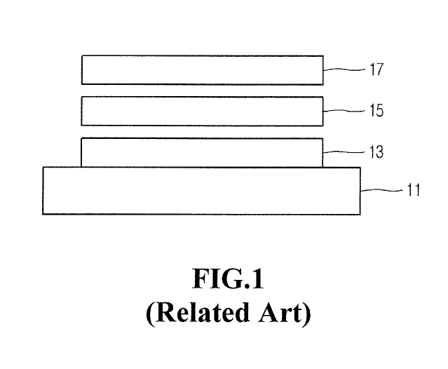

### DETAILED DESCRIPTION

In the description of embodiments of the present invention, when each layer (film), or structure is described to be formed “on/above” or “below/under” another layer (film) or structure, it can be understood as being directly contacted with the other layer or structure, or other layers or other structures are additionally formed therebetween. Therefore, the meanings should be judged according to the technical idea of the embodiment.

Hereinafter, embodiments of the present invention will be described in detail with reference to the accompanying drawings.

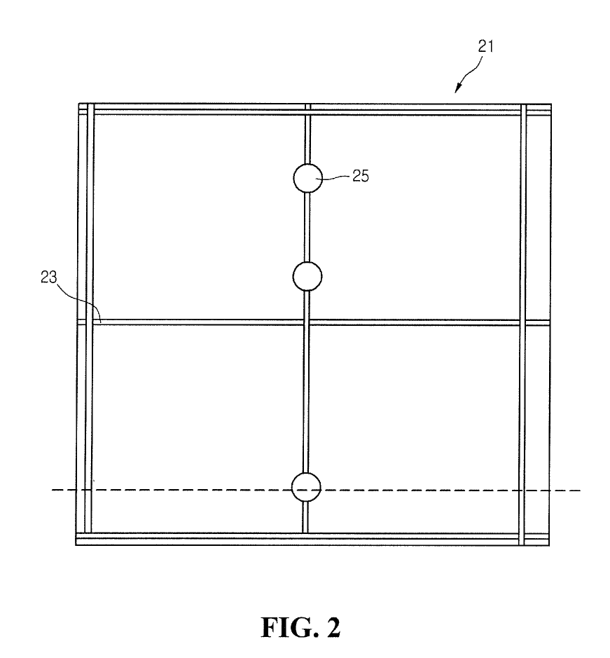

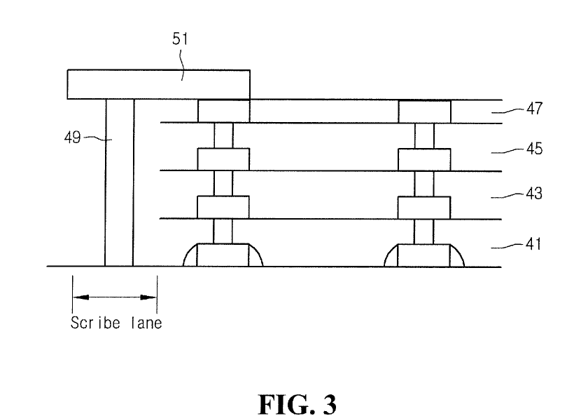

FIGS. 2 and 3 are views for explaining a semiconductor device according to an embodiment.

According to an embodiment, a scheme is provided for easily connecting signals between a device positioned on the upper surface of a semiconductor device in a SiP (System In a Package) and a device positioned on the lower surface thereof.

In an embodiment scheme, a through-electrode is formed on a scribe lane where a circuit is not provided in the semiconductor device. Ac cording to such an embodiment, the through-electrode in the semiconductor device in a SiP shape can be formed without damage of the circuit while connecting the upper device to the lower device.

FIG. 2 shows a layout example of a semiconductor device. As shown in FIG. 2, the semiconductor device is defined with circuit areas where a circuit is formed and a scribe lane 23 partitioning the boundary between the circuit areas. The circuit areas can comprise, for example, a logic circuit area and a memory area.

According to an embodiment, a semiconductor substrate 21 defined with a plurality of circuit areas where a circuit is to be formed and a scribe lane 23 partitioning the boundary between the circuit areas is prepared.

Then, a circuit unit is formed in the circuit area of the semiconductor substrate 21 and a through-electrode 25 is formed in the area defined with the scribe lane 23.

As shown in FIG. 2, scribe lanes 23 formed to partition the circuit areas exist in several places of the device. A through-electrode 25 should be formed for SiP shape applications. There fore, through-electrodes 25 can be formed in the area defined with the scribe lane 23, making it possible to prevent the circuit unit formed in the circuit area from being damaged.

In a further embodiment, the method includes forming a connecting electrode connecting a signal electrode formed on the circuit unit to the through-electrode 25.

As shown in FIG. 3, a connecting electrode 51 can be formed on the uppermost layer of the semiconductor device. A semiconductor device according to an embodiment can include a PMD (Pre Metal Dielectric) layer 41, a first IMD (Inter Metal Dielectric) layer 43, a second IMD layer 45, and a third IMD layer 47. Herein, the case where three IMD layers are formed is shown by way of example, but the number of the IMD layers can be formed in higher or lower numbers according to the design of the semiconductor device.

Also, the semiconductor device includes a through-electrode 49 penetrating through the device, as shown in FIG. 3. The through-electrode 49 can be formed by penetrating through the third IMD layer 47, the second IMD layer 45, the first IMD layer 43, and the PMD layer 41. Also, the through-electrode 49 can be formed by penetrating the semiconductor substrate from below the PMD layer 41, if necessary.

As shown in FIG. 3, the connecting electrode 51 can connect the through-electrode 49 to an uppermost metal wiring layer of the semiconductor device. The connecting electrode 51 can be formed using a patterning process in an uppermost metal wiring layer, and accordingly, the connecting electrode 51 can be connected to a metal wiring in the circuit area.

A process where the through-electrode 49 is formed on the semiconductor device will be described by way of example.

First, a semiconductor substrate having a transistor area therein is prepared, and a PMD layer 41 is formed on the semiconductor substrate.

Transistors are formed in the transistor area of the semiconductor substrate and the PMD layer 41 is formed on the transistors. A contact is formed on the PMD layer 41 to connect with various structures, such as a gate electrode of a transistor. Such a fabricating method of the PMD layer 41 and the transistors are known by those of ordinary skill in the art, thus the detailed description thereof will be omitted herein.

After the PMD layer 41 is formed at least one IMD layer is formed on the PMD layer 41. FIG. 3 illustrates the case where three IMD layers, first IMD layer 43, second IMD layer 45, and third IMD layer 47, are formed but embodiments are not limited thereto.

Then, a through-electrode 49 penetrating through the third, second, and first IMD layers 47, 45, and 43, and the PMD layer 41 is formed. In an embodiment the through-electrode 49 can be formed up to the boundary surface where the semiconductor substrate is exposed.

In one embodiment through-electrode 49 can be formed during formation of each metal layer by sequentially progressing a pattern process, an etching process, a formation process of metal, and a CMP process for the PMD layer 41, the first IMD layer 43, the second IMD layer 45, and the third IMD layer 47. In another embodiment the through-electrode can be formed as a separate pattern process.

The through-electrode 49 can be formed of at least one metal selected from the substance of W, Cu, Al, Ag, and Au. The through-electrode 49 can be deposited by means of CVD (chemical vapor deposition), PVD (physical vapor deposition), Evaporation, or ECP (electro chemical plating). A barrier metal can be included for the through-electrode 49. For example, the barrier metal can include at least one of TaN, Ta, TiN, Ti, and TiSIN.

The through-electrode 49 can be formed to penetrate through the semiconductor substrate. In a process of forming the through-electrode, the through-electrodes can collectively penetrate through the semiconductor substrate by separately performing an etching for the semiconductor substrate.

The semiconductor device fabricated according to such a fabricating method of the semiconductor device is defined with a plurality of circuit areas where a circuit is formed, and a scribe lane partitioning the boundary between the circuit areas. The semiconductor device includes a circuit unit formed in the circuit area and a through-electrode formed on the scribe lane and penetrating through the semiconductor device.

With the fabricating method of the semiconductor device according to an embodiment, the through-electrode can be formed on the scribe lane, making it possible to prevent the circuit unit formed in the circuit area from being damaged.

As described above, the semiconductor device and the fabricating method thereof according to embodiments of the present invention has an advantage that it can easily connect signals between the device positioned on the upper of the semiconductor device in a SiP (System In a Package) shape and the device positioned on the lower thereof.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a plurality of circuit areas and a scribe lane partitioning a boundary between the circuit areas;
a circuit unit formed in the circuit areas; and
a through-electrode formed in an area of the scribe lane.

2. The semiconductor device according to claim 1, wherein the through-electrode penetrates through the semiconductor device.

3. The semiconductor device according to claim 1, further comprising a connecting electrode connecting a signal electrode formed in the circuit unit to the through-electrode.

4. The semiconductor device according to claim 3, wherein the connecting electrode is connected to a top metal wiring layer of the signal electrode.

5. The semiconductor device according to claim 1, wherein the through-electrode is formed of at least one selected from the group consisting of W, Cu, Al, Ag, and Au.

6. The semiconductor device according to claim 1, wherein the plurality of circuit areas comprise a logic circuit area and a memory area.

7. A fabricating method of a semiconductor device comprising:
preparing a semiconductor substrate defining a plurality of circuit areas and a scribe lane partitioning a boundary between the circuit areas; and
forming a circuit unit in the circuit area of the semiconductor substrate and forming a through-electrode in the scribe lane.

8. The fabricating method according to claim 7, further comprising forming a connecting electrode connecting a signal electrode formed in the circuit unit to the through-electrode.

9. The fabricating method according to claim 8, wherein the connecting electrode is connected to a top metal wiring layer of signal electrode.

10. The fabricating method according to claim 7, wherein the through-electrode is formed of at least one selected from the group consisting of W, Cu, Al, Ag, and Au.

11. The fabricating method according to claim 7, wherein the plurality of circuit areas comprise a logic circuit area and a memory area.
